(19) United States
(12) Patent Application Publication
(10) Pub. No.: US 2013/0093430 A1
(43) Pub. Date: Apr. 18, 2013

(54) BATTERY STATE MEASURING METHOD AND APPARATUS

(71) Applicants: Hitoshi HAGIMORI, Tokyo (JP); Yosuke Mikami, Tokyo (JP)

(72) Inventors: Hitoshi HAGIMORI, Tokyo (JP); Yosuke Mikami, Tokyo (JP)

(73) Assignee: MITSUMI ELECTRIC CO., LTD.

(21) Appl. No.: 13/644,673

(22) Filed: Oct. 4, 2012

(30) Foreign Application Priority Data
Oct. 12, 2011 (JP) 2011-225273

(51) Int. Cl. G01R 31/36

(52) U.S. Cl. 324/434

(57) ABSTRACT

A battery state measuring method includes a voltage detecting step of detecting a transient open-circuit voltage of a secondary battery at an end of a fixed-length period starting at a termination of charging or discharging of the secondary battery, a parameter detecting step of detecting one or more parameters indicative of one or more battery states of the secondary battery at or prior to the end of the fixed-length period, and a prediction step of utilizing a relationship between the transient open-circuit voltage, the one or more parameters indicative of one or more battery states, and a stabilized open-circuit voltage of the secondary battery as observed after the end of the fixed-length period to obtain the stabilized open-circuit voltage that corresponds to the transient open-circuit voltage detected by the voltage detecting step and the one or more parameters detected by the parameter detecting step.

### BACKGROUND OF THE INVENTION

1. Field of the Invention

The disclosures herein relate to the technology for measuring the state of a secondary battery.

2. Description of the Related Art

A remaining battery level calculating apparatus is known in the art to derive a remaining battery level by detecting an open-circuit voltage of a battery and by comparing the detected open-circuit voltage with data indicative of the relationship between the open-circuit voltage and the remaining battery level (Japanese Patent Application Publication No. H03-180783, for example).

A time length required for an open-circuit voltage of a secondary battery to become stable varies depending on the ambient temperature, degradation rate, resistance value, and the like of the secondary battery. In order to detect a stable open-circuit voltage, it may be required to wait for a long time. Such a requirement may result in a decreased number of opportunities in which correction calculation is performed to obtain the remaining battery level of the secondary battery by use of a detected open-circuit voltage. It follows that there may a risk of having an increased calculation error in the remaining battery level.

Accordingly, it may be desired to provide a battery state measuring method and a battery state measuring apparatus that can estimate a stabilized open-circuit voltage in advance without waiting for the open-circuit voltage to become stable.

### SUMMARY OF THE INVENTION

It is a general object of the present invention to provide a battery state measuring method and a battery state measuring apparatus that substantially obviates one or more problems caused by the limitations and disadvantages of the related art.

According to one embodiment, a battery state measuring method includes a voltage detecting step of detecting a transient open-circuit voltage of a secondary battery at an end of a fixed-length period starting at a termination of charging or discharging of the secondary battery, a parameter detecting step of detecting one or more parameters indicative of one or more battery states of the secondary battery at or prior to the end of the fixed-length period, and a prediction step of utilizing a relationship between the transient open-circuit voltage, the one or more parameters indicative of one or more battery states, and a stabilized open-circuit voltage of the secondary battery as observed after the end of the fixed-length period to obtain the stabilized open-circuit voltage that corresponds to the transient open-circuit voltage detected by the voltage detecting step and the one or more parameters detected by the parameter detecting step.

According to another embodiment, an battery state measuring apparatus includes a voltage detecting unit configured to detect a transient open-circuit voltage of a secondary battery at an end of a fixed-length period starting at a termination of charging or discharging of the secondary battery, a parameter detecting configured to detect one or more parameters indicative of one or more battery states of the secondary battery at or prior to the end of the fixed-length period, and a prediction unit configured to utilize a relationship between the transient open-circuit voltage, the one or more parameters indicative of one or more battery states, and a stabilized open-circuit voltage of the secondary battery as observed after the end of the fixed-length period to obtain the stabilized open-circuit voltage that corresponds to the transient open-circuit voltage detected by the voltage detecting unit and the one or more parameters detected by the parameter detecting unit.

At least one embodiment, an open-circuit voltage can be estimated in advance without waiting for the open-circuit voltage to become stable.

### BRIEF DESCRIPTION OF THE DRAWINGS

Other objects and further features of the present invention will be apparent from the following detailed description when read in conjunction with the accompanying drawings, in which:

FIG. 1 is a block diagram illustrating an example of the configuration of a measurement circuit that is an embodiment of a battery state measuring apparatus;

FIG. 2 is a diagram illustrating battery characteristics indicative of the relationship between time and the battery voltage of a secondary battery before and after the termination of discharge;

FIG. 3 is a diagram illustrating battery characteristics indicative of the relationship between time and the battery voltage of the secondary battery before and after the termination of charge;

FIG. 4 is a diagram illustrating the relationship between a state-of-charge and a voltage difference after the termination of discharging of a secondary battery as actually measured for each degradation rate at temperature of 25 degrees Celsius;

FIG. 5 is a diagram illustrating the relationship between a state-of-charge and a voltage difference after the termination of discharging of an undegraded secondary battery as actually measured for each temperature;

FIG. 6 is a diagram illustrating the relationship between a state-of-charge and a voltage difference after the termination of charging of a secondary battery as actually measured for each degradation rate at temperature of 25 degrees Celsius;

FIG. 7 is a diagram illustrating the relationship between a state-of-charge and a voltage difference after the termination of charging of an undegraded secondary battery as actually measured for each temperature; and

FIG. 8 is a flowchart illustrating an example of calculation of a stabilized open-circuit voltage.

### DESCRIPTION OF THE PREFERRED EMBODIMENTS

In the following, embodiments of the present invention will be described with reference to the accompanying drawings.

In the following, embodiments of the present invention will be described by referring to the accompanying drawings.

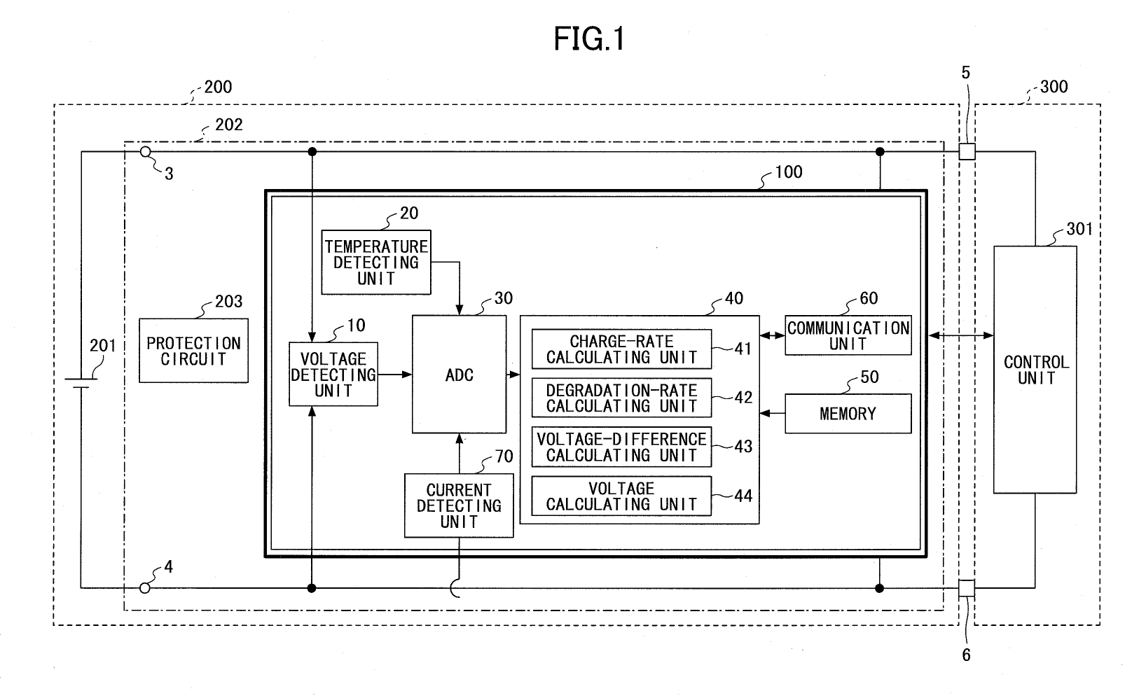

FIG. 1 is a block diagram illustrating an example of the configuration of a measurement circuit 100 that is an embodiment of a battery state measuring apparatus. The measurement circuit 100 is an integrated circuit (IC) that measures the remaining battery level of a secondary battery 201. Examples of the secondary battery 201 include a lithium-ion battery, a lithium-polymer battery, and the like.

The secondary battery 201 is embedded in a battery pack 200 that is contained inside or externally attached to an electronic apparatus 300. Examples of the electronic apparatus 300 include a portable terminal (such as a portable phone, a portable game machine, an information terminal, and a portable music or video player), a game machine, a computer, a headset, and a camera. The secondary battery 201 supplies power to the electronic apparatus 300 via load-connect terminals 5 and 6, and is chargeable by a charger (not shown) that is connected to the load-connect terminals 5 and 6.

The battery pack 200 includes the secondary battery 201 and a protection module 202 that is connected to the secondary battery 201 through battery-connection terminals 3 and 4. The protection module 202 is an apparatus for protecting a battery, and includes the measurement circuit 100 and a protection circuit 203 for protecting the secondary battery 201 from an abnormal state such as overcurrent, overcharge, overdischarge, and the like.

The measurement circuit 100 includes a voltage detecting unit 10, a temperature detecting unit 20, a current detecting unit 70, an AD converter (ADC) 30, an execution unit 40, a memory 50, and a communication unit 60.

The voltage detecting unit 10 detects a voltage between the two poles of the secondary battery 201, and supplies an analog voltage responsive to the detected voltage to the AD converter 30.

The temperature detecting unit 20 detects an ambient temperature of the secondary battery 201, and supplies an analog voltage responsive to the detected temperature to the AD converter 30. The temperature detecting unit 20 may detect the temperature of the measurement circuit 100 or the temperature of the electronic apparatus 300 as the ambient temperature of the secondary battery 201. The temperature detecting unit 20 may directly detect the temperature of the secondary battery 201 or may detect temperature inside the battery pack 200.

The current detecting unit 70 detects a charge or discharge current of the secondary battery 201, and supplies an analog voltage responsive to the detected current to the AD converter 30. The current detecting unit 70 may detect the current flowing through the negative-side power-supply path between the negative pole of the secondary battery 201 and the load-connect terminal 6.

The AD converter 30 converts the analog voltages supplied from the voltage detecting unit 10, the temperature detecting unit 20, and the current detecting unit 70 into digital values for provision to the execution unit 40.

The execution unit 40 estimates a battery state such as the remaining battery level of the secondary battery 201 based on the battery voltage of the secondary battery 201 detected by the voltage detecting unit 10, the temperature of the secondary battery 201 detected by the temperature detecting unit 20, and characteristic data representing the battery characteristics of the secondary battery 201 stored in advance in the memory 50. The charge or discharge current of the secondary battery 201 detected by the current detecting unit 70 may additionally be used to estimate the battery state of the secondary battery 201. The execution unit 40 includes a charge-rate calculating unit 41, a degradation-rate calculating unit 42, a voltage-difference calculating unit 43, and a voltage calculating unit 44. These calculating units will be described later. An example of the execution unit 40 includes a computing device such as a microcomputer. An example of the memory 50 includes a nonvolatile memory device such as an EEPROM.

The communication unit 60 is an interface that transmits data of a battery state such as the remaining battery level of the secondary battery 201 to a control unit 301 embedded in the electronic apparatus 300. Examples of the control unit 301 include a CPU for performing control operations of the electronic apparatus 300, a charge or discharge control IC for controlling a charge/discharge operation of the secondary battery 201, and the like. Based on the battery state such as the remaining battery level of the secondary battery 201 obtained from the measurement circuit 100, the control unit 301 performs a predetermined control operation such as an operation of displaying the remaining battery level of the secondary battery 201 for a user.

In the following, the battery characteristics of the secondary battery 201 will be described.

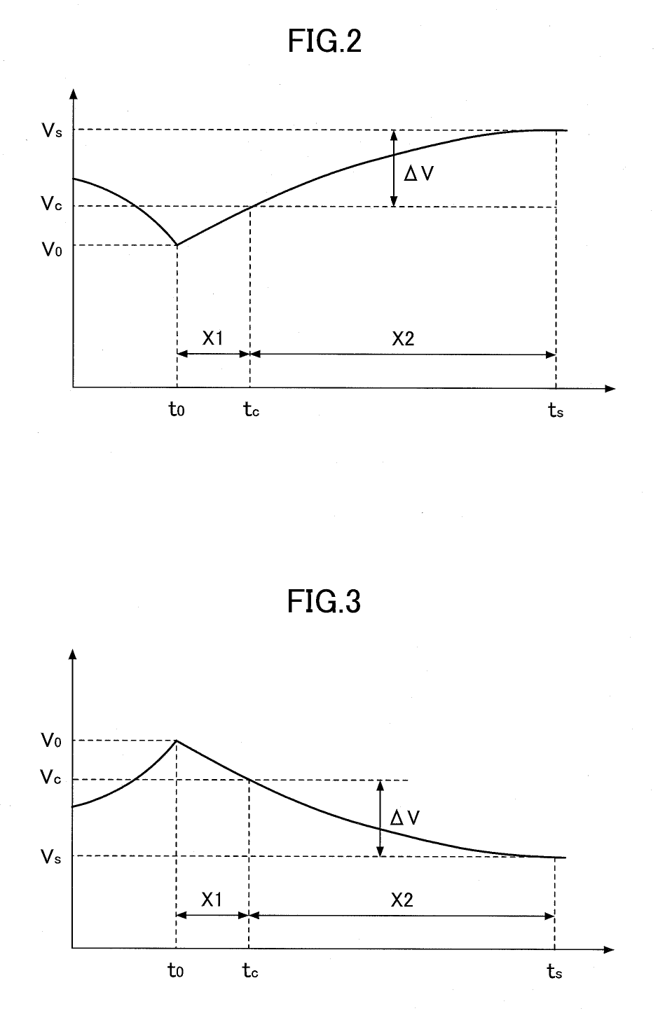

FIG. 2 is a diagram illustrating battery characteristics indicative of the relationship between time t and a battery voltage V of the secondary battery 201 before and after the termination of discharge. FIG. 3 is a diagram illustrating battery characteristics indicative of the relationship between time t and a battery voltage V of the secondary battery 201 before and after the termination of charge. t₀ indicates a point in time at which the charge or discharge of the secondary battery 201 is terminated. V₀ indicates a battery voltage of the secondary battery 201 as detected at the charge/discharge termination time t₀. The battery voltage (i.e., open-circuit voltage) of the secondary battery 201, observed during the charge/discharge termination state following the time t₀, increases or decreases with time due to changes in the internal state of the secondary battery 201. A time length such as 20 hours may pass before the open-circuit voltage of the secondary battery 201 reaches a stable level.

The open-circuit voltage of the secondary battery 201 observed at time t_{c} that marks the end of a fixed-length period X1 starting at the charge/discharge termination time t₀ is defined as a transient open-circuit voltage V_{c}. Further, the open-circuit voltage of the secondary battery 201 observed at time tₛ that marks the end of a fixed-length period X2 starting at the time t_{c} is defined as a stabilized open-circuit voltage Vₛ. ΔV is defined as a voltage difference between V_{c} and Vₛ. X1 and X2 are fixed-length, constant time periods. X2 is significantly longer than X1 such that the open-circuit voltage becomes the stabilized open-circuit voltage Vs in a sense that a change per unit time in the open-circuit voltage becomes smaller than a predetermined voltage (e.g., 10 mV).

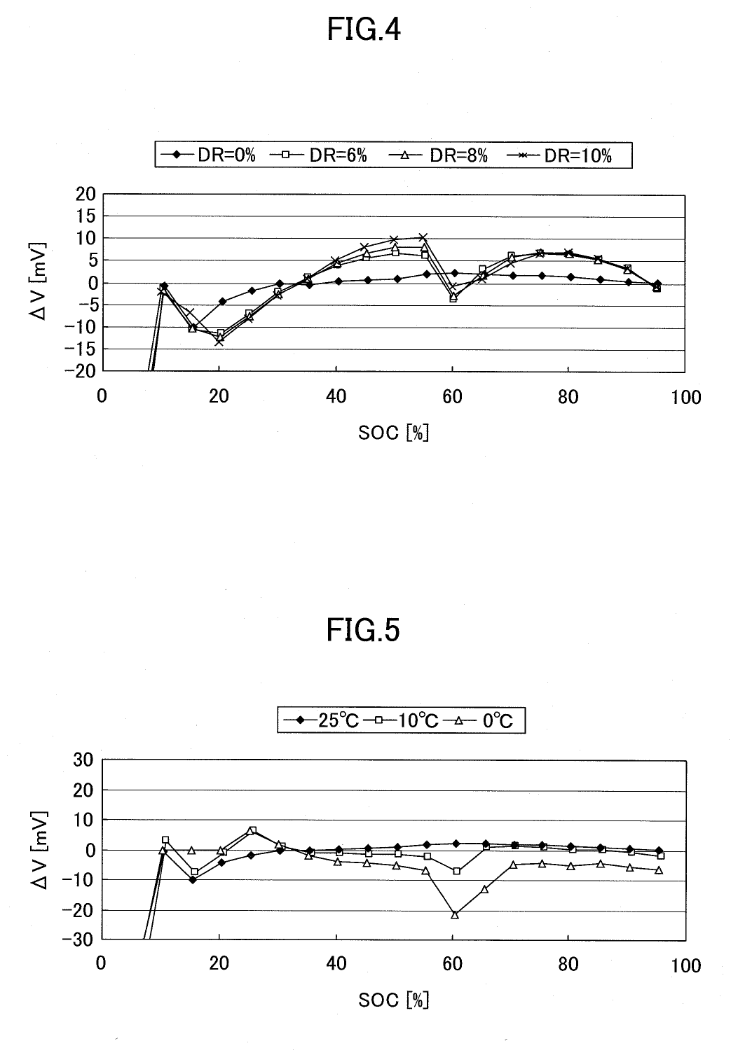

FIG. 4 is a diagram illustrating the relationship between a state-of-charge SOC and a voltage difference ΔV after the termination of discharging of the secondary battery 201 as actually measured for each degradation rate DR at temperature T of 25 degrees Celsius. FIG. 5 is a diagram illustrating the relationship between a state-of-charge SOC and a voltage difference ΔV after the termination of discharging of the undegraded secondary battery 201 as actually measured for each temperature T. The values of the state-of-charge SOC, the degradation rate DR, and the temperature T used in FIG. 4 and FIG. 5 are the values detected or calculated at the time t_{c} that marks the end of the fixed-length period X1 starting at the discharge termination time t₀ of the secondary battery 201.

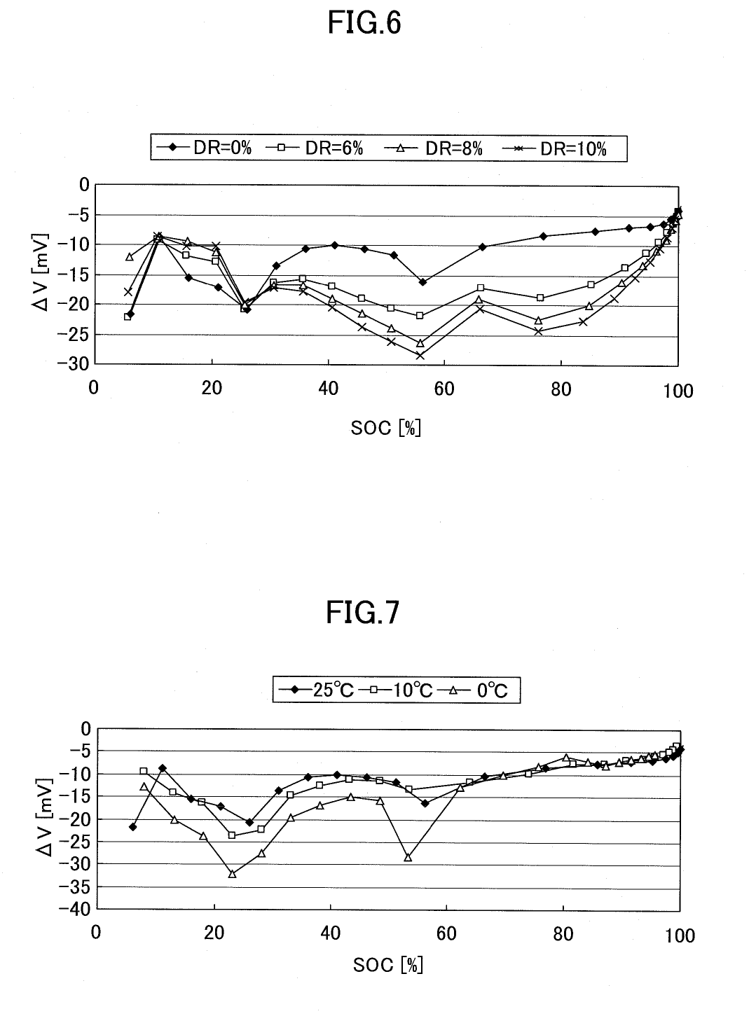

FIG. 6 is a diagram illustrating the relationship between a state-of-charge SOC and a voltage difference ΔV after the termination of charging of the secondary battery 201 as actually measured for each degradation rate DR at temperature T of 25 degrees Celsius. FIG. 7 is a diagram illustrating the relationship between a state-of-charge SOC and a voltage difference ΔV after the termination of charging of the undegraded secondary battery 201 as actually measured for each temperature T. The values of the state-of-charge SOC, the degradation rate DR, and the temperature T used in FIG. 6 and FIG. 7 are the values detected or calculated at the time t_{c} that marks the end of the fixed-length period X1 starting at the charge termination time t₀ of the secondary battery 201.

It is understood from FIG. 4, FIG. 5, FIG. 6, and FIG. 7 that the voltage difference ΔV varies in response to a change in parameters S indicative of battery states such as the state-of-charge SOC, the degradation rate DR, and the temperature T.

In consideration of this, battery characteristics representing the relationships between the voltage difference ΔV and the parameters S indicative of battery states are obtained in advance based on the actually measured data illustrated in FIG. 4, FIG. 5, FIG. 6, and FIG. 7. The execution unit 40 of the measurement circuit 100 uses such battery characteristics obtained in advance to calculate a voltage difference ΔV corresponding to detected values of the parameters S indicative of battery states. The battery characteristics representing the relationships between the voltage difference ΔV and the parameters S indicative of battery states may be provided as an approximation formula or as a table. Once the voltage difference ΔV is calculated, and the transient open-circuit voltage Vc is measured at the time t_{c}, the execution unit 40 can use the following formula to calculate the stabilized open-circuit voltage Vₛ that would be observed at the time tₛ.

V_{S}=V_{c}+ΔV (1)

Namely, the execution unit 40 can estimate (i.e., predict), at the time t_{c} prior to tₛ, the stabilized open-circuit voltage Vₛ that would be observed at the time tₛ. As is clear from FIG. 2 and FIG. 3, the stabilized open-circuit voltage Vs following the termination of charge/discharge can be calculated by adding ΔV to Vc as shown in formula (1) (ΔV can assume either a positive value or a negative value).

In the following, a description will be given of approximation formulas that approximate the battery characteristics representing the relationships between the voltage difference ΔV and the parameters S indicative of battery states. In FIG. 4, FIG. 5, FIG. 6, and FIG. 7, points on the SOC axis at which ΔV converges or ΔV exhibits a sudden change may be used as segmenting points. The approximation formulas may then be defined for each of the segments defined by these segmenting points.

The voltage difference ΔV may be represented by the following formula for each SOC segment that is defined in advance, based on the relationships illustrated in FIG. 4 and FIG. 6 actually measured at 25 degrees Celsius.

ΔV=a₂·SOC²+a₁·SOC+a₀ (2)

Here, aᵢ is a coefficient (i=0, 1, 2).

From the graphs illustrated in FIG. 4 and FIG. 6, each aᵢ approximately has a quadratic characteristic with respect to the degradation rate DR, and may thus be represented as follows.

aᵢ=aᵢ₂·DR²+aᵢ₁·DR+aᵢₒ (3)

Here, ₐⱼ is a coefficient (i=0, 1, 2, j=0, 1, 2).

Accordingly, the voltage-difference calculating unit 43 of the execution unit 40 can use the formulas (2) and (3) to calculate the voltage difference ΔV at 25 degrees Celsius that corresponds to the state-of-charge SOC as calculated by the charge-rate calculating unit 41 and the degradation rate DR as calculated by the degradation-rate calculating unit 42.

Further, the voltage difference ΔV has temperature dependency, as illustrated in FIG. 5 and FIG. 7, which show values actually measured for the secondary battery 201 having a degradation rate DR of 0%. From the graphs illustrated in FIG. 5 and FIG. 7, each aᵢⱼ appearing in formula (3) approximately has a linear characteristic with respect to the temperature T, and may thus be represented as follows.

aᵢⱼ=aᵢⱼ₁·T+aᵢⱼ₀ (4)

Here, aᵢⱼₖ is a coefficient (i=0, 1, 2, j=0, 1, 2, k=0, 1).

Accordingly, the voltage-difference calculating unit 43 of the execution unit 40 can use the formulas (2), (3), and (4) to calculate the voltage difference ΔV that corresponds to the state-of-charge SOC as calculated by the charge-rate calculating unit 41, the degradation rate DR as calculated by the degradation-rate calculating unit 42, and the temperature as detected by the temperature detecting unit 20.

Accordingly, the voltage calculating unit of the execution unit 40 can calculate the stabilized open-circuit voltage Vₛ by substituting the voltage difference ΔV as calculated above and the transient open-circuit voltage V_{c} as detected by the voltage detecting unit 10 into formula (1).

Formulas (2), (3), and (4) are examples only. Although a quadratic expression is used for approximation in formulas (2) and (3) and a linear expression is used for approximation in formula (4), other function expressions may be used for approximation. An approximation formula or a coefficient of each term in the approximation formula may be changed for different ranges of a parameter such as the state-of-charge SOC, the degradation rate DR, or the temperature T. Further, an approximation formula or a coefficient of each term in the approximation formula may be changed between the case in which the open-circuit voltage following the termination of discharge is estimated and the case in which the open-circuit voltage following the termination of charge is estimated. In this manner, proper model functions may be used in consideration of battery characteristics that may differ for different types of the secondary battery 201. Coefficients of such an approximation formula and coefficients for determining such coefficients may be stored in the memory 50 in advance.

In the following, a description will be given of an example of calculation of the stabilized open-circuit voltage Vₛ by the execution unit 40.

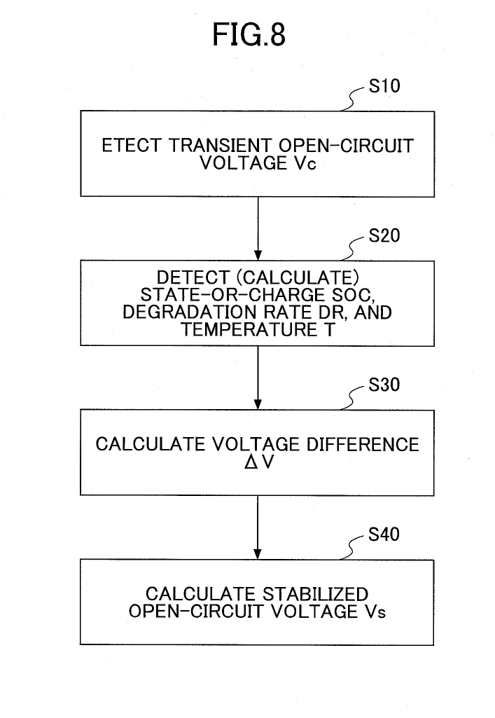

FIG. 8 is a flowchart showing an example of calculation of the stabilized open-circuit voltage Vₛ. The execution unit 40 uses the charge-rate calculating unit 41, the degradation-rate calculating unit 42, the voltage-difference calculating unit 43, and the voltage calculating unit 44 to perform the routine illustrated in the flowchart of FIG. 8 each time the charging or discharging of the secondary battery 201 is terminated.

In step S10, the execution unit 40 measures an open-circuit voltage detected at the time t_{c} by the voltage detecting unit 10 as the transient open-circuit voltage V_{c}. For example, the execution unit 40 detects a time at which a charge/discharge current detected by the current detecting unit 70 diminishes to zero or to become smaller than a predetermined value close to zero, and treats such a detected time as the charge/discharge termination time t₀. The execution unit 40 obtains an open-circuit voltage detected by the voltage detecting unit 10 at the time t_{c} that marks the end of the fixed-time period X1 starting at the charge/discharge termination time t₀, and treats such a detected voltage as the transient open-circuit voltage V_{c}.

In step S20, the charge-rate calculating unit 41 uses the battery voltage of the secondary battery 201 detected by the voltage detecting unit 10 and the charge/discharge current detected by the current detecting unit 70 to calculate the state-of-charge SOC of the secondary battery 201. Any known method of calculation may be used to calculate the state-of-charge SOC of the secondary battery 201. The degradation-rate calculating unit 42 may calculate a ratio of the current full-charge capacity of the secondary battery 201 to the initial full-charge capacity of the secondary battery 201, and uses the calculated ratio as the degradation ratio DR. Any known method of calculation may be used to calculate the degradation rate DR of the secondary battery 201. The temperature detecting unit 20 detects the temperature of the secondary battery 201.

In step S30, the voltage-difference calculating unit 43 uses the formulas (2), (3), and (4) to calculate the voltage difference ΔV that corresponds to the state-of-charge SOC, the degradation rate DR, and the temperature T as calculated or detected in step S20.

In step S40, the voltage calculating unit 44 uses the formula (1) to calculate the stabilized open-circuit voltage Vₛ by use of the transient open-circuit voltage V_{c} detected in step S10 and the voltage difference ΔV calculated in step S30.

Accordingly, as illustrated in FIG. 8, a stabilized open-circuit voltage can be estimated in advance without waiting for the open-circuit voltage of the secondary battery 201 to become stable.

Since the stabilized open-circuit voltage can be predicted in advance before actual stabilization, the number of opportunities in which correction execution to obtain a remaining battery level is performed increases. Further, since the stabilized open-circuit voltage can be predicted by taking into account the parameters indicative of battery states such as the state-of-charge SOC, the degradation rate DR, and the temperature T, an accurate state-of-charge SOC can be calculated based on a table that shows the relationship between the open-circuit voltage and the state-of-charge, for example. Moreover, reduction in the length of time required to calculate an open-circuit voltage and improvement in calculation accuracy can improve the usability of products using a secondary battery. The execution unit 40 can detect a failure of the secondary battery 201 in the event that the state-of-charge SOC calculated from the stabilized open-circuit voltage Vs is different by more than a predetermined threshold from the state-of-charge SOC obtained through a different calculation (for example, calculated from integrated capacity).

Further, the present invention is not limited to these embodiments, but various variations and modifications may be made without departing from the scope of the present invention.

For example, the battery state measuring apparatus may not have to be implemented on a substrate on which the protection module 202 of the battery pack 200 is mounted. The battery state measuring apparatus may be implemented on a substrate in the electronic apparatus 300 that operates on the secondary battery 201. Further, the battery state measuring method may be integrated into the software that is run by the control unit 301 of the electronic apparatus 300.

The parameters S indicative of battery states (such as the state-of-charge SOC, the degradation rate DR, and the temperature T) for use in calculation of the stabilized open-circuit voltage Vₛ preferably have such values as observed or obtained at the timing t_{c} at which the transient open-circuit voltage V_{c} is measured. Alternatively, these parameters S may have values that are observed or obtained at a point in time preceding t_{c} (e.g., values observed after the charge/discharge termination time t₀ and before t_{c}) and as recent as possible.

The parameters S indicative of battery states for use in calculation of the stable-stage open-circuit voltage Vs may be any parameters indicative of other states different from the state-of-charge SOC, the degradation rate DR, and the temperature T as long as the states indicated by these parameters exhibit correlation with the voltage difference ΔV.

The present application is based on Japanese priority application No. 2011-225273 filed on Oct. 12, 2011, with the Japanese Patent Office, the entire contents of which are hereby incorporated by reference.

What is claimed is:

1. A battery state measuring method, comprising:
a voltage detecting step of detecting a transient open-circuit voltage of a secondary battery at an end of a fixed-length period starting at a termination of charging or discharging of the secondary battery;
a parameter detecting step of detecting one or more parameters indicative of one or more battery states of the secondary battery at or prior to the end of the fixed-length period; and
a prediction step of utilizing a relationship between the transient open-circuit voltage, the one or more parameters indicative of one or more battery states, and a stabilized open-circuit voltage of the secondary battery as observed after the end of the fixed-length period to obtain the stabilized open-circuit voltage that corresponds to the transient open-circuit voltage detected by the voltage detecting step and the one or more parameters detected by the parameter detecting step.

2. The battery state measuring method as claimed in claim 1, wherein the prediction step includes:
a voltage difference calculating step of utilizing a relationship between the one or more parameters indicative of one or more battery states and a voltage difference between the transient open-circuit voltage and the stabilized open-circuit voltage to calculate the voltage difference that corresponds to the one or more parameters detected by the parameter detecting step; and
a voltage calculating step of calculating the stabilized open-circuit voltage by use of the transient open-circuit voltage detected by the voltage detecting step and the voltage difference calculated by the voltage difference calculating step.

3. The battery state measuring method as claimed in claim 1, wherein the one or more parameters indicative of one or more battery states include at least one of a state-of-charge, temperature, and a degradation rate of the secondary battery.

4. An battery state measuring apparatus, comprising:
a voltage detecting unit configured to detect a transient open-circuit voltage of a secondary battery at an end of a fixed-length period starting at a termination of charging or discharging of the secondary battery;
a parameter detecting configured to detect one or more parameters indicative of one or more battery states of the secondary battery at or prior to the end of the fixed-length period; and
a prediction unit configured to utilize a relationship between the transient open-circuit voltage, the one or more parameters indicative of one or more battery states, and a stabilized open-circuit voltage of the secondary battery as observed after the end of the fixed-length period to obtain the stabilized open-circuit voltage that corresponds to the transient open-circuit voltage detected by the voltage detecting unit and the one or more parameters detected by the parameter detecting unit.

5. A battery protection apparatus, comprising:
the battery state measuring apparatus of claim 4; and
a protection circuit configured to protect the secondary battery.

6. A battery pack, comprising:
the battery state measuring apparatus of claim 4; and
the secondary battery.

7. An electronic apparatus operating on a secondary battery, comprising:
the battery state measuring apparatus of claim 4.
